(19) United States
(12) Patent Application Publication
(10) Pub. No.: US 2015/0365107 A1
(43) Pub. Date: Dec. 17, 2015

(54) DATA TRANSMISSION METHOD AND APPARATUS

(71) Applicant: ELECTRONICS AND TELECOMMUNICATIONS RESEARCH INSTITUTE, Daejeon (KR)

(72) Inventors: Seung-Soo LEE, Daejeon (KR); Seong-Jun SHIN, Daejeon (KR); Jeong-Seok LIM, Daejeon (KR); Jung-Gil PARK, Daejeon (KR)

(21) Appl. No.: 14/475,870

(22) Filed: Sep. 3, 2014

(30) Foreign Application Priority Data
Jun. 11, 2014 (KR) 10-2014-0070500

(51) Int. Cl. H03M 13/27; H03M 13/00; H03M 13/19

(52) U.S. Cl. CPC H03M 13/2778; H03M 13/19; H03M 13/611

(57) ABSTRACT

A data transmission method and apparatus, which can improve transmission efficiency and securely perform communication without increasing the bandwidth of encrypted data in an environment in which a transmission success rate for encrypted data is changeable depending on the quality of a network. In the method, a network quality of a channel is measured, and a lossy compression scheme or a lossless compression scheme is selected depending on results of measurement. Original data to be transmitted is compressed so that the original data is compressed using the selected compression scheme. Compressed data is encrypted. ECC encoding is performed on encrypted data, and ECC-encoded data is interleaved.

### CROSS REFERENCE TO RELATED APPLICATION

This application claims the benefit of Korean Patent Application No. 10-2014-0070500 filed Jun. 11, 2014, which is hereby incorporated by reference in its entirety into this application.

### BACKGROUND OF THE INVENTION

1. Technical Field

The present invention relates generally to a data transmission method and apparatus and, more particularly, to a data transmission method and apparatus which more securely transmit encrypted data in a poor quality network environment.

2. Description of the Related Art

Conventional technology relates to methods and apparatuses for data traffic control which can strengthen security against the decryption of received data by inserting error correction codes and errors into ciphers or which can select compression schemes and ciphers depending on the transfer rate in a mobile communication environment.

Such conventional technology merely increases the efficiency of communication by selecting an optimal compression and cryptographic algorithm depending on computation speed and network conditions.

As related preceding technology, Korean Patent Application Publication No. 10-2011-0119269 presents technology for selecting an optimal compression algorithm and an optimal cryptographic algorithm in a changeable environment in which the computation speeds of a transmission side and a reception side and the condition of a network are changed in real time, thus improving the efficiency of communication.

As another preceding technology, Korean Patent Application Publication No. 10-2013-0020980 presents technology for improving an encryption level to better than that of existing encryption systems based on an error correction code.

### SUMMARY OF THE INVENTION

Accordingly, the present invention has been made keeping in mind the above problems occurring in the prior art, and an object of the present invention is to provide a data transmission method and apparatus, which can improve transmission efficiency and securely perform communication without increasing the bandwidth of encrypted data in an environment in which a transmission success rate for encrypted data is changeable depending on the quality of a network.

In accordance with an aspect of the present invention to accomplish the above object, there is provided a data transmission method, including measuring, by a network quality measurement unit, a network quality of a channel and selecting, by the network quality measurement unit, a lossy compression scheme or a lossless compression scheme, depending on results of measurement; compressing, by a compression unit, original data to be transmitted so that the original data is compressed using the selected compression scheme; encrypting, by an encryption unit, compressed data; performing, by an error correction code (ECC) encoder, ECC encoding on encrypted data; and interleaving, by an interleaver, ECC-encoded data.

Selecting the compression scheme may include, when, as a result of measurement of the network quality, a Bit Error Rate (BER) is 10⁻², regarding the network as a poor network and then selecting the lossy compression scheme.

Compressing the original data may include performing lossy compression using a 1/10 compression algorithm.

Performing the ECC encoding may include performing ECC encoding using a (7, 4) Hamming code.

The data transmission method may further include, when performing lossy compression, repetitively transmitting, by a repetitive transmitter, the ECC-encoded data to the interleaver a plurality of times.

Selecting the compression scheme may include when, as a result of measurement of the network quality, a BER is 10⁻⁴, regarding the network as a good network and selecting the lossless compression scheme.

Compressing the original data may include performing lossless compression using a ⅓ compression algorithm.

Performing the ECC encoding may include performing ECC encoding using a (15, 11) Hamming code.

Interleaving the ECC-encoded data may be configured such that an amount of interleaved data is identical to an amount of the original data.

In accordance with another aspect of the present invention to accomplish the above object, there is provided a data transmission apparatus, including a network quality measurement unit for measuring a network quality of a channel and selecting a lossy compression scheme or a lossless compression scheme depending on results of measurement; a compression unit for lossily compressing or losslessly compressing original data to be transmitted in response to a selection signal output from the network quality measurement unit; an encryption unit for encrypting data lossily compressed or losslessly compressed by the compression unit; an error correction code (ECC) encoder for performing ECC encoding on data encrypted by the encryption unit; and an interleaver for interleaving data ECC-encoded by the ECC encoder.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a configuration diagram showing a data transmission apparatus according to an embodiment of the present invention;

FIG. 2 is a flowchart showing a data transmission method according to an embodiment of the present invention;

FIG. 3 is a flowchart showing a reception operation performed by the data transmission apparatus according to an embodiment of the present invention; and

FIG. 4 is a diagram showing the structure of a data frame employed in an embodiment of the present invention.

### DESCRIPTION OF THE PREFERRED EMBODIMENTS

The present invention may be variously changed and may have various embodiments, and specific embodiments will be described in detail below with reference to the attached drawings.

However, it should be understood that those embodiments are not intended to limit the present invention to specific disclosure forms and they include all changes, equivalents or modifications included in the spirit and scope of the present invention.

The terms used in the present specification are merely used to describe specific embodiments and are not intended to limit the present invention. A singular expression includes a plural expression unless a description to the contrary is specifically pointed out in context. In the present specification, it should be understood that the terms such as “include” or “have” are merely intended to indicate that features, numbers, steps, operations, components, parts, or combinations thereof are present, and are not intended to exclude a possibility that one or more other features, numbers, steps, operations, components, parts, or combinations thereof will be present or added.

Unless differently defined, all terms used here including technical or scientific terms have the same meanings as the terms generally understood by those skilled in the art to which the present invention pertains. The terms identical to those defined in generally used dictionaries should be interpreted as having meanings identical to contextual meanings of the related art, and are not interpreted as being ideal or excessively formal meanings unless they are definitely defined in the present specification.

Embodiments of the present invention will be described in detail with reference to the accompanying drawings. In the following description of the present invention, the same reference numerals are used to designate the same or similar elements throughout the drawings and repeated descriptions of the same components will be omitted.

The following embodiments of the present invention are intended to describe technology for transmitting encrypted data while minimizing errors in the encrypted data via optimal combinations of compression schemes and error correction codes (ECCs) depending on the quality of a network, thus strengthening the survivability of data.

That is, the present invention relates to technology for performing efficient cryptographic communication depending on network quality when important information is encrypted and transmitted. In particular, the present invention enables encrypted data to be transmitted without increasing bandwidth. By means of this, more secure cryptographic communication may be performed even in a poor communication environment, and optimized communication schemes may be provided upon designing crypto-equipment and communication equipment for military purposes.

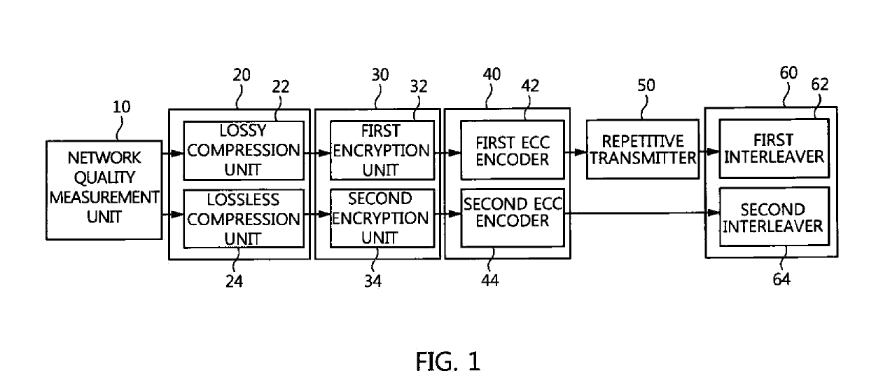

FIG. 1 is a configuration diagram showing a data transmission apparatus according to an embodiment of the present invention.

The data transmission apparatus according to the embodiment of the present invention includes a network quality measurement unit 10, a compression unit 20, an encryption unit 30, an error correction code (ECC) encoder 40, a repetitive transmitter 50, and an interleaver 60.

The network quality measurement unit 10 measures the network quality of a channel, and selects either of lossy compression and lossless (non-lossy) compression as a compression scheme depending on the results of measurement of network quality. The network quality measurement unit 10 transmits selected results to the compression unit 20.

For example, as a result of measurement of network quality, when a Bit Error Rate (BER) is 10⁻², the network quality measurement unit 10 regards the network as a poor network and selects lossy compression, whereas when a BER is 10⁻⁴, the network quality measurement unit 10 regards the network as a good network and selects lossless compression. In this case, the core principle of the present invention is that, in a poor network, original data is maximally compressed compared to that in a good network, and a strong ECC is inserted into the data. In the embodiment of the present invention, reference values depending on the measurement of network quality are not presented as specific values. In the embodiment of the present invention, encrypted data is combined using communication methods, such as compression, ECC, repetitive transmission, and interleaving, depending on the network quality measured by the network quality measurement unit 10, and then the survivability of transmitted data is strengthened.

The compression unit 20 compresses data to be transmitted using lossy compression or lossless compression in response to a compression scheme selection signal output from the network quality measurement unit 10. The compression unit 20 includes a lossy compression unit 22 and a lossless compression unit 24.

Accordingly, if a signal indicating that a lossy compression scheme has been selected is received from the network quality measurement unit 10, the lossy compression unit 22 lossily compresses the data to be transmitted. In this case, the lossy compression unit 22 may use a 1/10 compression algorithm.

Further, if a signal indicating that a lossless compression scheme has been selected is received from the network quality measurement unit 10, the lossless compression unit 24 losslessly compresses the data to be transmitted. In this case, the lossless compression unit 24 may use a ⅓ compression algorithm.

The encryption unit 30 encrypts data compressed by the compression unit 20. The encryption unit 30 includes a first encryption unit 32 and a second encryption unit 34.

Accordingly, the first encryption unit 32 encrypts data lossily compressed by the lossy compression unit 22. In this case, the first encryption unit 32 may perform encryption using an Advanced Encryption Standard (AES) algorithm.

Further, the second encryption unit 34 encrypts data losslessly compressed by the lossless compression unit 24. In this case, the second encryption unit 34 may perform encryption using the AES algorithm.

In FIG. 1, the encryption unit 30 is divided into the first encryption unit 32 and the second encryption unit 34, but the encryption units may be integrated into a single encryption unit depending on circumstances.

The ECC encoder 40 performs ECC encoding on the data encrypted by the encryption unit 30. The ECC encoder 40 includes a first ECC encoder 42 and a second ECC encoder 44.

Accordingly, the first ECC encoder 42 performs encoding causing redundant information to be added to the encrypted data output from the first encryption unit 32. For example, the first ECC encoder 42 may perform ECC encoding using a (7,4) Hamming code. Those skilled in the art will easily understand ECC encoding using a Hamming code from a well-known technology even if an additional description thereof is not made.

Further, the second ECC encoder 44 performs encoding causing redundant information to, be added to the encrypted data output from the second encryption unit 34. For example, the second ECC encoder 44 may perform ECC encoding using a (15, 11) Hamming code.

The repetitive transmitter 50 repetitively transmits frame-based data output from the first ECC encoder 42 to the interleaver 60 a plurality of times. For example, the repetitive transmitter 50 may repetitively transmit the data about five times. That is, the repetitive transmitter 50 is used only when the quality of a network is poor, and may perform either simple repetition or irregular repetition. In the description, ‘five times’ may be only an example and the number of repetitions of transmission may be increased or decreased depending on circumstances.

The interleaver 60 interleaves the, data output from the repetitive transmitter 50, or the data on which encryption based on lossless compression and ECC encoding have been performed. The interleaver 60 includes a first interleaver 62 for interleaving the data output from the repetitive transmitter 50 and a second interleaver 64 for interleaving the data on which encryption based on lossless compression and ECC encoding have been performed.

The function of the interleaver 60 is to tolerate burst errors caused by a bit slip in a wireless environment. After going through the interleaver 60, data is finally transmitted.

The above-described data transmission apparatus according to the embodiment of the present invention lossily compresses data and then encrypts the compressed data via the first encryption unit 32 if the measured network quality is determined to be poor. Upon encryption, data is not increased. Further, after going through the strong ECC encoder (that is, the first ECC encoder) 42, the data goes through the repetitive transmitter 50 and is then transmitted through the first interleaver 62. For example, lossy compression is implemented using a 1/10 compression algorithm, compressed data is encrypted using the AES algorithm, encrypted data is ECC-encoded using the (7,4) Hamming code, an encoded frame is repetitively transmitted five times, and transmitted data is interleaved and then transmitted. In this way, the present invention may obtain the advantages of correcting errors even in the presence of the errors during transmission, without increasing transmission traffic for original data, thus strengthening the survivability of data. In an embodiment of the present invention, lossy compression is assumed to enable data to be compressed to 1/200. Therefore, in actual implementation, as examples of application, there may be combinations of various lossy compression techniques and error correction codes (ECCs).

Further, in an embodiment of the present invention, the sequence of lossy compression and encryption is not fixed, but is variable. That is, encryption may be first performed and compression may be subsequently performed.

Meanwhile, if the measured network quality is determined to be good, data is losslessly compressed and is then encrypted via the second encryption unit 34. Further, encrypted data is ECC-encoded via the ECC encoder (that is, the second ECC encoder) 44 that is weaker than that used in lossy compression, and encoded data is transmitted via the second interleaver 64. In this case, since the network quality is excellent, repetitive transmission is assumed to be unnecessary. For example, lossless compression is implemented using a ⅓ compression algorithm, compressed data is encrypted using the AES algorithm, encrypted data is ECC-encoded using the (15, 11) Hamming code, and encoded data is interleaved and transmitted. In an embodiment of the present invention, lossless compression is assumed to enable data to be compressed to 1/16. Even in this case, in actual implementation, there may be combinations of various lossless compression techniques and error correction codes. However, when network quality is good, combinations in which repetitive transmission is not used are implemented so that there is not an unnecessary increase in data to be transmitted.

The present invention does not specify and propose compression techniques and ECCs. That is, typical compression techniques and ECCs may be used. However, the present invention proposes a transmission method and procedure for strengthening the survivability of data upon transmitting encrypted data without increasing the amount of data to be transmitted.

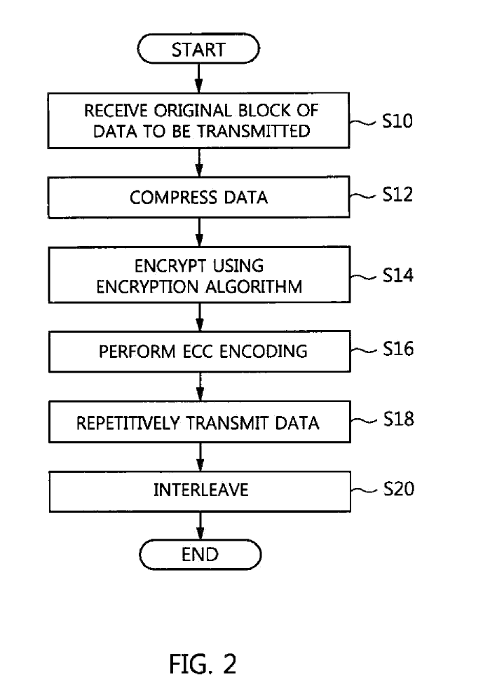

FIG. 2 is a flowchart showing a data transmission method according to an embodiment of the present invention.

First, the network quality measurement unit 10 measures the network quality of a channel through which data is to be transmitted, and transmits the results of measurement of the network quality to the compression unit 20.

Accordingly, the compression unit 20 receives an original block of data to be transmitted, and compresses the data depending on the current network quality at steps S10 and S12. For example, when network quality is poor, the data is lossily compressed using a 1/10 compression algorithm, whereas when network quality is good, the data is losslessly compressed using a ⅓ compression algorithm.

Then, the encryption unit 30 encrypts compressed data output from the compression unit 20 using an AES algorithm at step S14.

Thereafter, the ECC encoder 40 performs ECC encoding on the encrypted data output from the encryption unit 30 at step S16. For example, when network quality is poor, the encrypted data goes through ECC encoding using a (7, 4) Hamming code, whereas when network quality is good, the encrypted data goes through ECC encoding using a (15, 11) Hamming code.

Thereafter, repetitive transmission of the encoded data is performed by the repetitive transmitter 50 only in a case where network quality is poor at step S18. When network quality is good, there is no need to perform repetitive transmission.

Finally, the interleaver 60 interleaves data output from the repetitive transmitter 50 or the second ECC encoder 44, combines the interleaved data, and transmits the combined data to the reception unit at step S20.

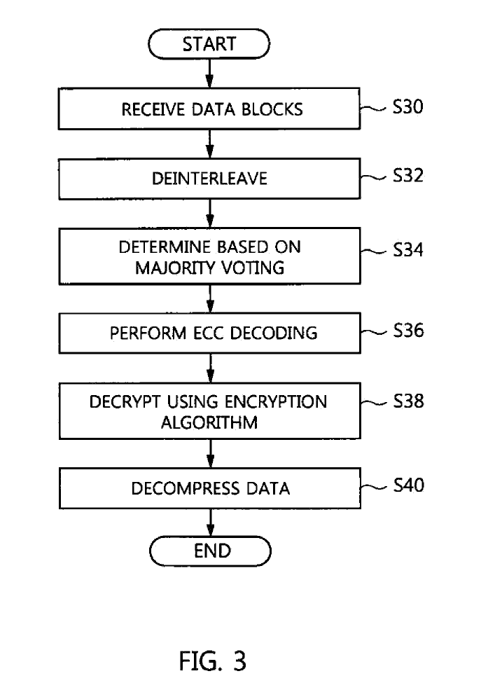

FIG. 3 is a flowchart showing a reception operation performed by the data transmission apparatus according to an embodiment of the present invention.

It is assumed that components for the reception operation are included in the data transmission apparatus according to an embodiment of the present invention. Although the components of an apparatus for the reception operation are not separately illustrated, those skilled in the art will easily expect that a reception procedure is performed based on a structure including a deinterleaver, a received data determination unit, an ECC decoder, an encryption algorithm decryption unit, and a decompression unit, from the above description because the reception procedure is the reverse of the transmission procedure.

If data blocks are received at step S30, the reception procedure is performed in the reverse order of the transmission procedure.

That is, the received data blocks are deinterleaved at step S32, and received data is determined based on majority voting at, step S34.

Thereafter, ECC decoding is performed on the received data at step S36. If an error exceeding a reference is detected in the received data, notification of occurrence of the error is provided to a transmission unit. In this case, the transmission unit re-measures network quality, and retransmits data using a data transmission method optimized for the network quality.

If any error is not detected, the data is decrypted using an encryption algorithm at step S38, and the decrypted data is decompressed, and then original data is reconstructed at step S40.

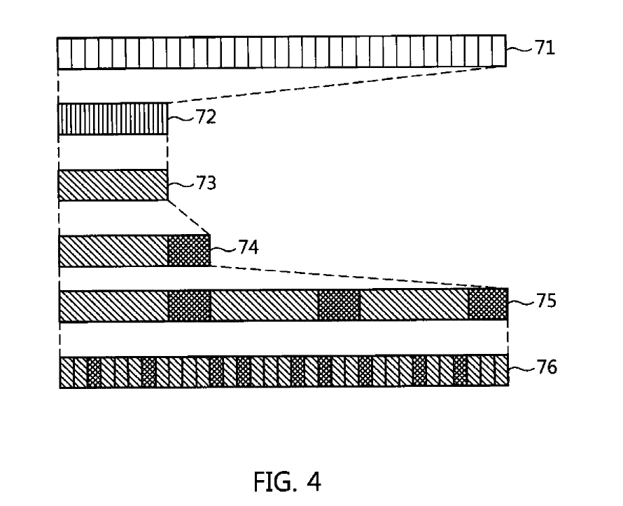

FIG. 4 is a diagram showing the structures of data frames employed in an embodiment of the present invention.

In FIG. 4, reference numeral 71 indicates the structure of an original data frame, reference numeral 72 indicates the structure of a compressed data frame, reference numeral 73 indicates the structure of an encrypted data frame, reference numeral 74 indicates the structure of an ECC-encoded data frame, reference numeral 75 indicates the structure of a repetitively transmitted data frame, and reference numeral 76 indicates the structure of an interleaved data frame.

FIG. 4 illustrates variations in a data frame structure occurring during data transmission for easy understanding of the present invention. The core concept of the drawing is that when the amount of original data 71 is compared with the amount of finally interleaved data 76, the amount of data is not increased.

In accordance with the present invention having the above configuration, the survivability of data is guaranteed during the transmission of encrypted data, and the encrypted data can be securely transmitted without increasing the bandwidth thereof. Therefore, it is expected that, when communication equipment or crypto-equipment for military purposes that must be operated in a poor communication environment is developed in the future, the technology of the invention may be applied as core base technology to the design of transmission/reception devices capable of improving operational employment performance.

As described above, optimal embodiments of the present invention have been disclosed in the drawings and the specification. Although specific terms have been used in the present specification, these are merely intended to describe the present invention and are not intended to limit the meanings thereof or the scope of the present invention described in the accompanying claims. Therefore, those skilled in the art will appreciate that various modifications and other equivalent embodiments are possible from the embodiments. Therefore, the technical scope of the present invention should be defined by the technical spirit of the claims.

What is claimed is:

1. A data transmission method, comprising:
measuring, by a network quality measurement unit, a network quality of a channel and selecting, by the network quality measurement unit, a lossy compression scheme or a lossless compression scheme, depending on results of measurement;
compressing, by a compression unit, original data to be transmitted so that the original data is compressed using the selected compression scheme;
encrypting, by an encryption unit, compressed data;
performing, by an error correction code (ECC) encoder, ECC encoding on encrypted data; and
interleaving, by an interleaver, ECC-encoded data.

2. The data transmission method of claim 1, wherein selecting the compression scheme comprises, when, as a result of measurement of the network quality, a Bit Error Rate (BER) is 10⁻², regarding the network as a poor network and then selecting the lossy compression scheme.

3. The data transmission method of claim 2, wherein compressing the original data comprises performing lossy compression using a 1/10 compression algorithm.

4. The data transmission method of claim 3, wherein performing the ECC encoding comprises performing ECC encoding using a (7, 4) Hamming code.

5. The data transmission method of claim 1, further comprising, when performing lossy compression, repetitively transmitting, by a repetitive transmitter, the ECC-encoded data to the interleaver a plurality of times.

6. The data transmission method of claim 1, wherein selecting the compression scheme comprises when, as a result of measurement of the network quality, a BER is 10⁻⁴, regarding the network as a good network and selecting the lossless compression scheme.

7. The data transmission method of claim 6, wherein compressing the original data comprises performing lossless compression using a ⅓ compression algorithm.

8. The data transmission method of claim 7, wherein performing the ECC encoding comprises performing ECC encoding using a (15, 11) Hamming code.

9. The data transmission method of claim 1, wherein interleaving the ECC-encoded data is configured such that an amount of interleaved data is identical to an amount of the original data.

10. A data transmission apparatus, comprising:
a network quality measurement unit for measuring a network quality of a channel and selecting a lossy compression scheme or a lossless compression scheme depending on results of measurement;
a compression unit for lossily compressing or losslessly compressing original data to be transmitted in response to a selection signal output from the network quality measurement unit;
an encryption unit for encrypting data lossily compressed or losslessly compressed by the compression unit;
an error correction code (ECC) encoder for performing ECC encoding on data encrypted by the encryption unit; and
an interleaver for interleaving data ECC-encoded by the ECC encoder.

11. The data transmission apparatus of claim 10, wherein the network quality measurement unit is configured to, when, as a result of measurement of the network quality, a Bit Error Rate (BER) is 10⁻², regard the network as a poor network and then select the lossy compression scheme.

12. The data transmission apparatus of claim 11, wherein the compression unit performs lossy compression using a 1/10 compression algorithm.

13. The data transmission apparatus of claim 12, wherein the ECC encoder performs ECC encoding using a (7, 4) Hamming code.

14. The data transmission apparatus of claim 10, further comprising a repetitive transmitter for, when lossy compression is performed, repetitively transmitting the ECC encoded data output from the ECC encoder to the interleaver a plurality of times.

15. The data transmission apparatus of claim 10, wherein the network quality measurement unit is configured to, when, as a result of measurement of the network quality, a BER is 10⁻⁴, regard the network as a good network and select the lossless compression scheme.

16. The data transmission apparatus of claim 15, wherein the compression unit performs lossless compression using a ⅓ compression algorithm.

17. The data transmission apparatus of claim 16, wherein the ECC encoder performs the ECC encoding using a (15, 11) Hamming code.

18. The data transmission apparatus of claim 10, wherein an amount of data interleaved by the interleaver is identical to an amount of the original data.
